(19) United States
(12) Patent Application Publication
(10) Pub. No.: US 2023/0126033 A1
(43) Pub. Date: Apr. 27, 2023

(54) HANDLE STRUCTURE OF SERVER CASE

(71) Applicant: NEXCOM INTERNATIONAL CO., LTD., New Taipei City (TW)

(72) Inventor: Hsin-Yi LEE, New Taipei City (TW)

(21) Appl. No.: 17/510,061

(22) Filed: Oct. 25, 2021

(51) Int. Cl. H05K 5/02; H05K 7/14

(52) U.S. Cl. CPC H05K 5/023; H05K 7/1488

(57) ABSTRACT

A handle structure includes a handle board, a pair of washers and a fastener set. The handle board includes a plate, a fixing section, and a holding section. The fixing section is formed with a through hole. The pair of washers includes a first washer and a second washer. The fastener set includes a first fastener and a second fastener. The first fastener passes through the first washer, the through hole, the second washer and a connecting hole in order. The first fastener is fixed on the panel by the second fastener. The handle board is rotatable about the through hole. The handle structure of a server case may be simplified.

### BACKGROUND

### Technical Field

The disclosure relates to a handle structure, particularly to a handle structure of a server case.

### Related Art

To deal with the requirements of access of a large amount of electronic data, many companies are usually equipped with server systems for storing the electronic data in the same place to provide convenient search and access of required information for users, and to easily back up and protect data.

Further, because users need to draw or replace a storage device in a server case, the outside of the case is usually equipped with a handle to be pushed or pulled to move the case to further draw out the storage device.

Also, the handle structure of the server case is disposed on a panel of the case. Because the handle structure is complicated and has a thicker overall thickness, it may occupy the panel area and affect the wiring and arrangement of the panel IO. Besides, the fixing between the handle and the panel usually adopts a latch structure. That makes the handle structure complicated and expensive, and increases cumbrance and inconvenience in the assembling process.

### SUMMARY

An object of the disclosure is to provide a handle structure of a server case, which may simplify the handle structure and the assembling manner.

To accomplish the above object, the disclosure is a handle structure of a server case, which is used for connecting to a panel with a connecting hole. The handle structure includes a handle board, a pair of washers and a fastener set. The handle board includes a plate, a fixing section and a holding section. The fixing section and the holding section are located on opposite sides of the plate. The fixing section is formed with a through hole. The pair of washers includes a first washer and a second washer disposed on two sides of the through hole. The fastener set includes a first fastener and a second fastener combined correspondingly. The first fastener passes through the first washer, the through hole, the second washer and the connecting hole in order. The first fastener is fixed on the panel by the second fastener. The handle board is rotatable about the through hole as a center.

In comparison with the related art, the handle structure of the disclosure includes a handle board, a pair of washers and a fastener set. The handle structure is simple and easily to be assembled. The handle board may be connected on the panel by the fastener set and does not occupy excessive areas of the panel. In addition, plastic washers are disposed on two sides of the handle board. The handle board may be rotated and positioned at any angles through the arrangement of the plastic washers to achieve the purpose of simplifying the handle structure and increasing the utility in use.

### BRIEF DESCRIPTION OF THE DRAWINGS

FIG. 1 is an exploded view of the handle structure of a server case of the disclosure;

FIGS. 2 and 3 are two schematic views, which show the handle structure of the disclosure is assembled on the panel;

FIG. 4 is a partially cross-sectional view of the handle structure of the disclosure assembled on the panel;

FIG. 5 is a perspective schematic view of the handle structure of the server case of the disclosure assembled in a server rack;

FIG. 6 is an assembled cross-sectional view of the handle structure of the server case of the disclosure assembled in a server rack; and

FIGS. 7-10 are schematic views of the handle structure of the server case of the disclosure assembled in a server rack in use.

### DETAILED DESCRIPTION

The technical contents of this disclosure will become apparent with the detailed description of embodiments accompanied with the illustration of related drawings as follows. It is intended that the embodiments and drawings disclosed herein are to be considered illustrative rather than restrictive.

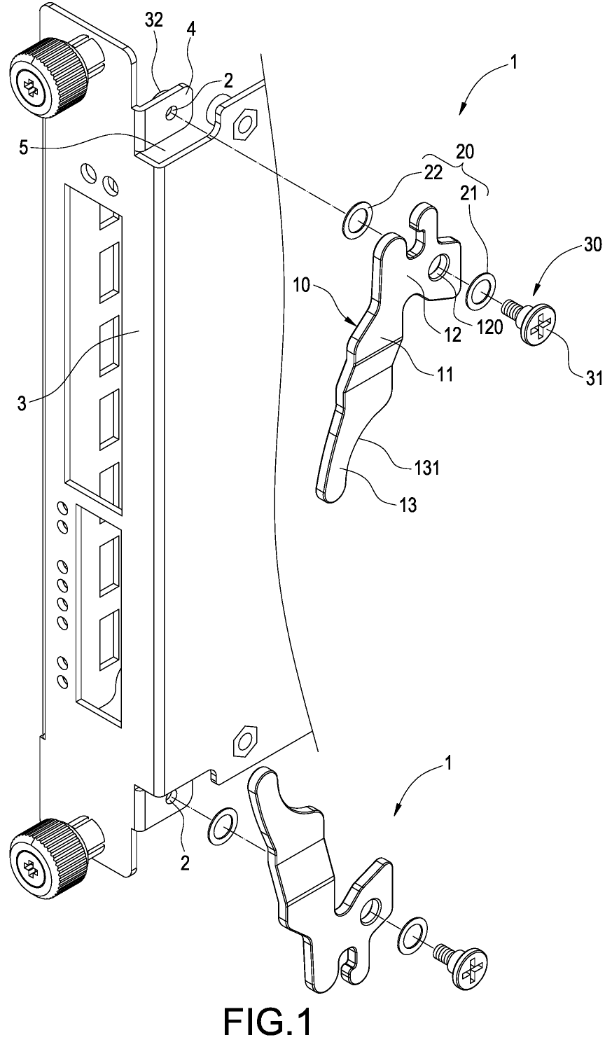

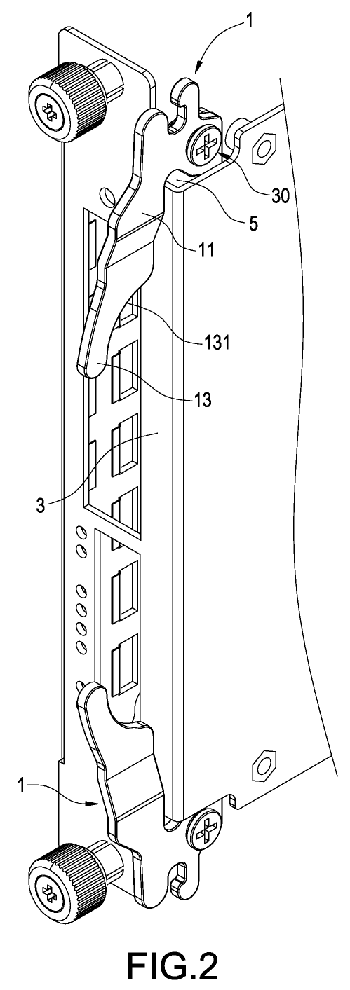

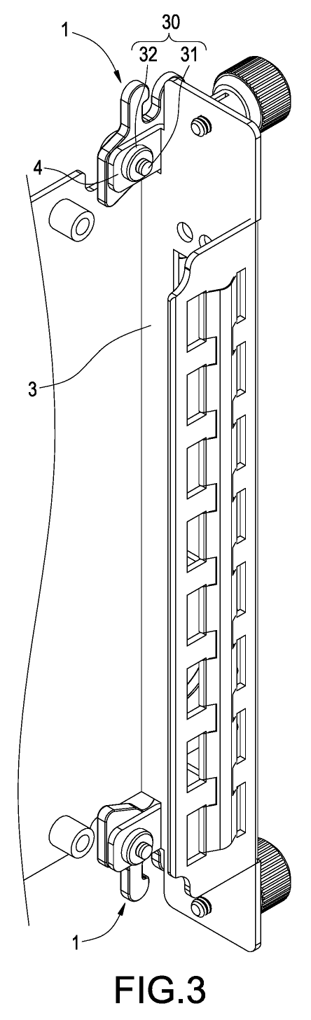

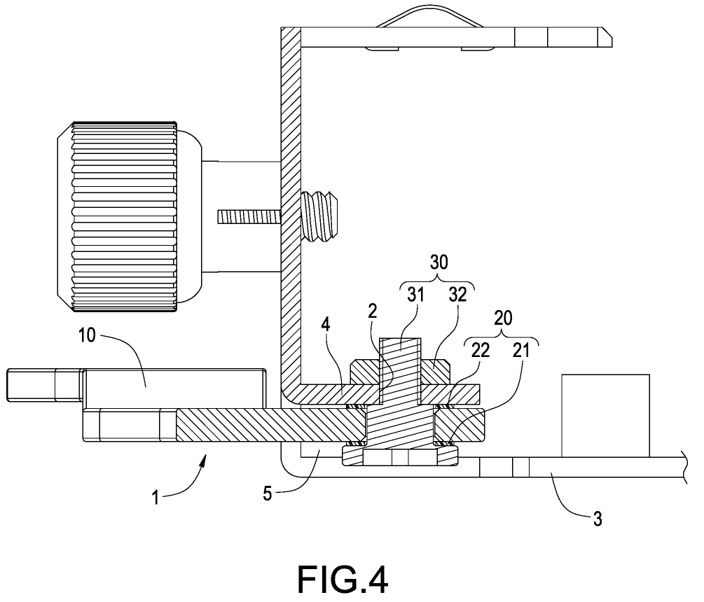

Please refer to FIGS. 1-4, which are an exploded view of the handle structure of the server case of the disclosure, two schematic views showing the handle structure assembled on the panel and a partially cross-sectional view of the handle structure assembled on the panel. The handle structure 1 of the server case of the disclosure is used to connect on a panel 3 with a connecting hole 2. The handle structure 1 includes a handle board 10, a pair of washers 20 and a fastener set 30. The pair of washers 20 is disposed on two sides of the handle board 10. The handle board 10 is connected to the connecting hole 2 of the panel 3 by the fastener set 30 to constitute the handle structure 1. The details of the handle structure 1 are described below.

The handle board 10 includes a plate 11, a fixing section 12 and a holding section 13. The fixing section 12 and the holding section 13 are located on opposite sides of the plate 11. The fixing section 12 is formed with a through hole 120. In some embodiments, a periphery of the handle board 10 is disposed with a chamfer to avoid scratching users.

The pair of washers 20 include a first washer 21 and a second washer 22, which are disposed on two sides of the through hole 120. In the embodiment, the pair of washers 20 are in a manner of plastic spacers respectively, such as, but not limited to, Teflon.

The fastener set 30 includes a first fastener 31 and a second fastener 32, which are combined correspondingly. The first fastener 31 passes through the first washer 21, the through hole 120, the second washer 22 and the connecting hole 2 in order. The first fastener 31 is fixed on the panel 3 by the second fastener 32. The handle board 10 is rotatable about the through hole 120 as a center. In addition, the handle board 10 may be rotated and positioned at any angle through the pair of washers 20.

In the embodiment, each of two sides of the panel 3 is provided with one connecting hole 2 and one handle structure 1. In other words, the panel 3 may be drawn and moved through the handle structures 1 on two sides.

In detail, the panel 3 is bent to form a protrusive plate 4 and a hollow trench 5 located on a side of the protrusive plate 4. The protrusive plate 4 is formed with the connecting hole 2. The fixing section 12 of the handle board 10 is located in the hollow trench 5. In addition, the holding section 13 of the handle board 10 includes an arcuate surface 131 which is located at a distal end of the holding section 13 and faces the panel 3. The arcuate surface 131 is advantageous for holding to increase safety when using.

In an embodiment of the disclosure, the first fastener 31 is a screw and the second fastener 32 is a nut. In some embodiments, the second fastener 32 may be positioned on the connecting hole 2 of the panel 3 to facilitate the assembling of the handle structure 1 to increase convenience when assembling.

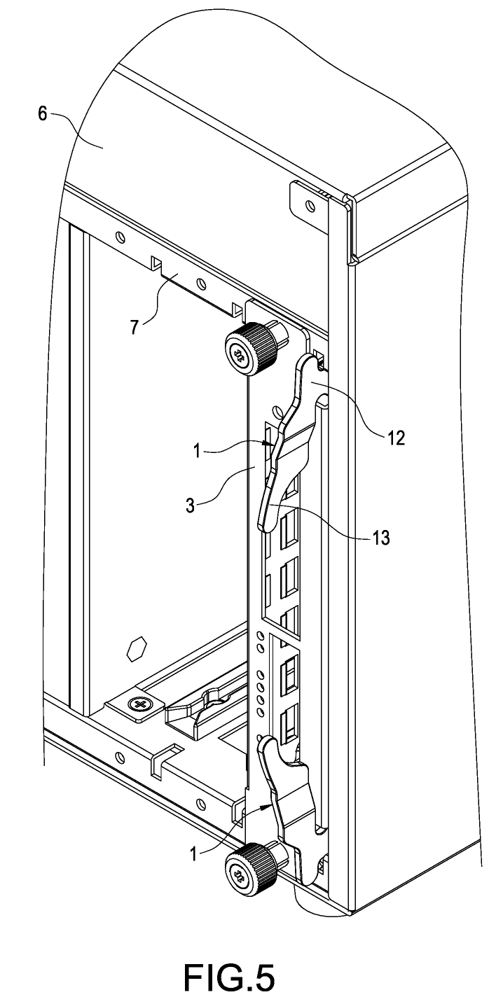

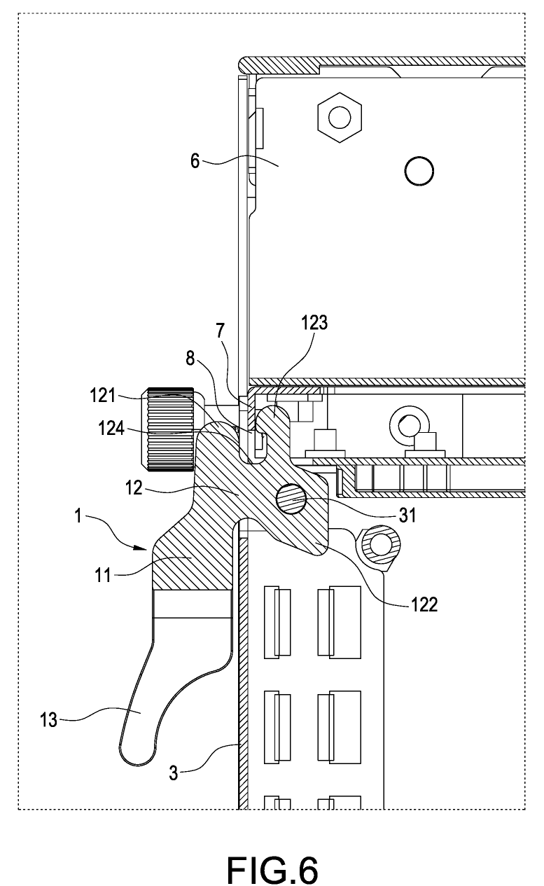

Please refer to FIGS. 5 and 6, which are a perspective schematic view and an assembled cross-sectional view of the handle structure of the server case of the disclosure assembled in a server rack. As shown in figures, the handle structure 1 of the disclosure is connected to a panel 3, the panel 3 is assembled on a server case 6. In the embodiment, a side of the server case 6, which is adjacent to the panel 3, has a frame plate 7, and the frame plate 7 is disposed with a passing hole 8.

In detail, as shown in FIG. 6, the fixing section 12 of the handle board 10 has a first engaging block 121 and a second engaging block 122. When the panel 3 abuts against the frame plate 7 and the handle board 10 is unrotated, the first engaging block 121 and the second engaging block 122 are correspondingly located on two sides of the frame plate 7. In addition, the fixing section 12 is formed spacedly with a third engaging block 123 on a side of the first engaging block 121. The third engaging block 123 passes through the passing hole 8 and abuts against the frame plate 7 when the handle board 10 is unrotated.

It is noted that a U-shaped opening 124 is formed between the first engaging block 121 and the third engaging block 123. The U-shaped opening 124 is correspondingly located on a side of the passing hole 8.

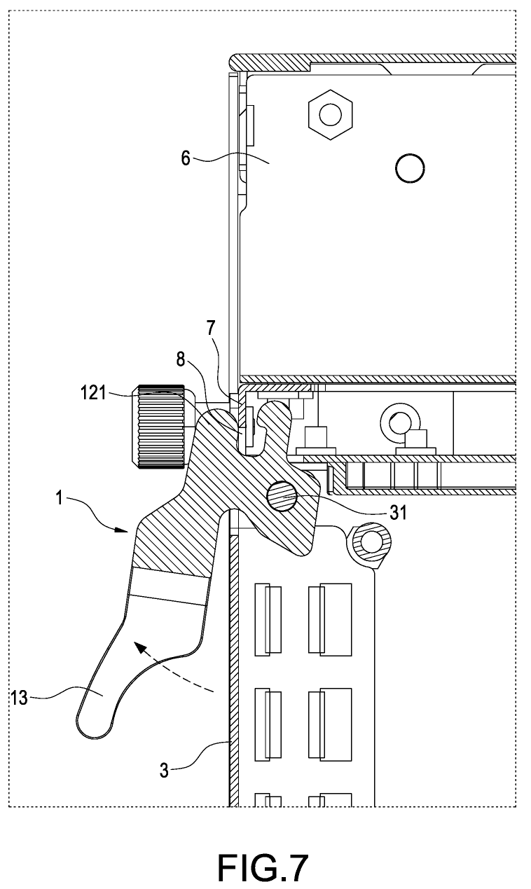

Please refer to FIGS. 7-10, which are schematic views of the handle structure of the server case of the disclosure assembled in a server rack in use. The handle structure 1 of the disclosure is connected on the panel 3 of the server case 6. The handle board 10 is rotated to facilitate the action of drawing the server case 6. As shown in FIG. 7, when a user exerts a force on the holding section 13 of the handle board 10, the first engaging block 121 presses on the frame plate 7.

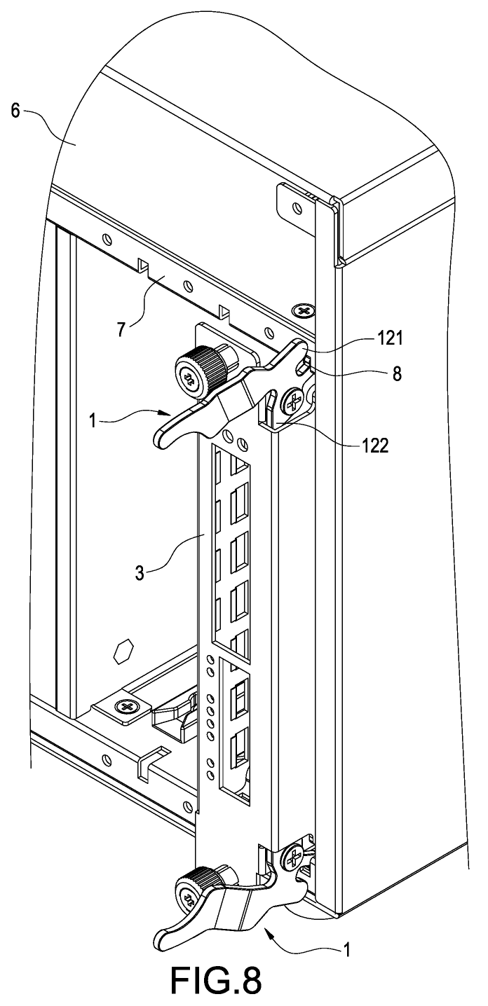

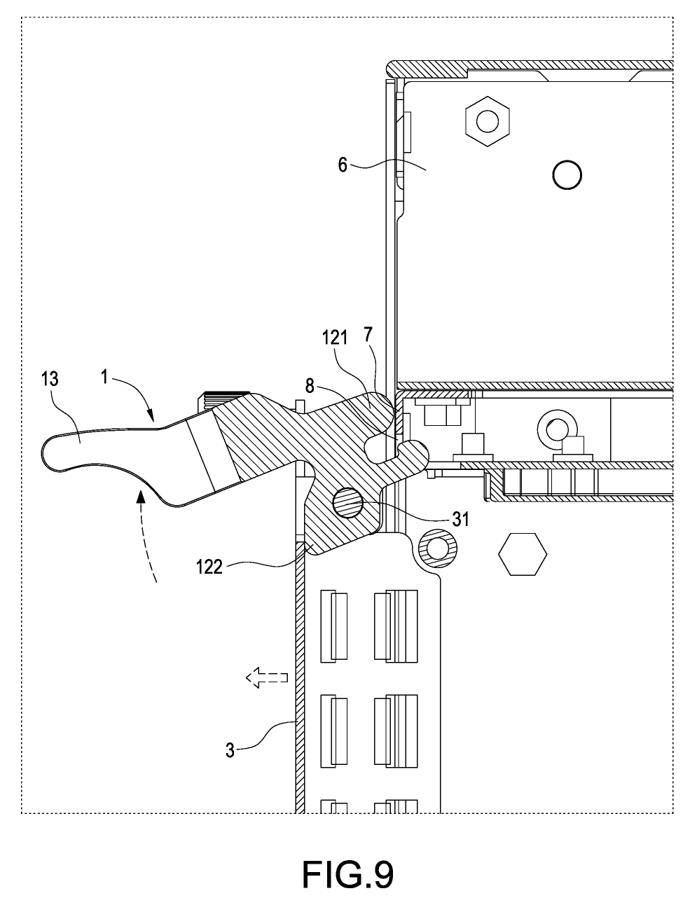

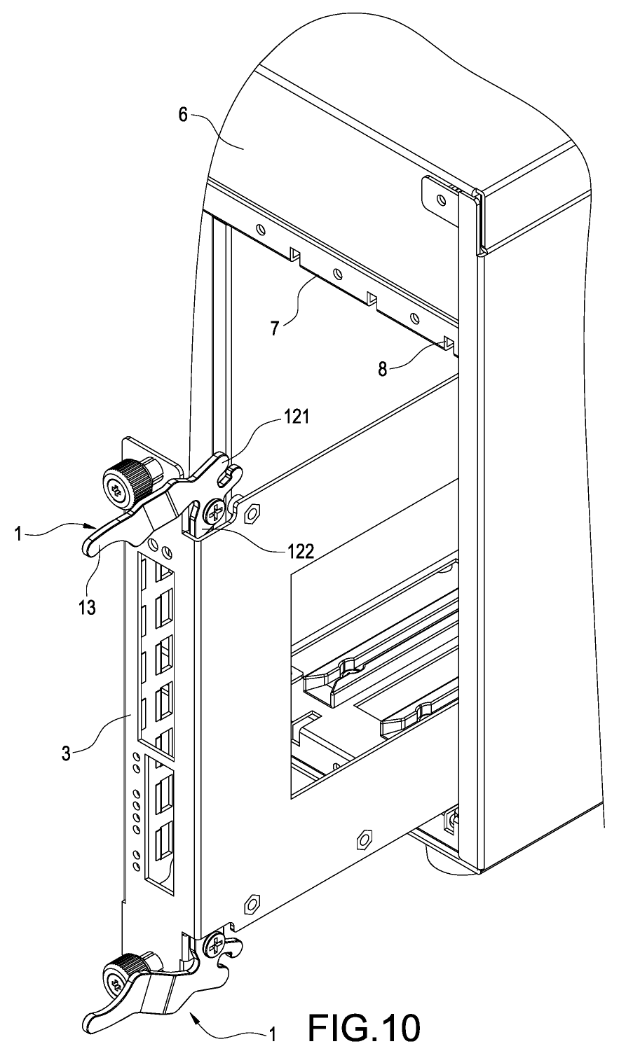

Please refer to FIGS. 8 and 9. When a force is exerted to rotate the handle board 10, the second engaging block 122 abuts against a lateral side of the panel 3. At the same time, the panel 3 is pushed by the first engaging block 121 and the second engaging block 122 to be withdrawn from the server case 6. As a result, as shown in FIG. 10, the server case 6 may be drawn through the handle structures 1 on two sides.

While this disclosure has been described by means of specific embodiments, numerous modifications and variations could be made thereto by those skilled in the art without departing from the scope and spirit of this disclosure set forth in the claims.

1. A handle structure of a server case, which is used for connecting to a panel with a connecting hole, the handle structure comprising:
a single handle board, comprising a fixing section and a holding section, the fixing section and the holding section located on opposite sides of the handle board, and the fixing section comprising a through hole disposed thereon;
a pair of washers, comprising a first washer and a second washer disposed on two sides of the through hole; and
a fastener set, comprising a first fastener and a second fastener combined correspondingly, the first fastener passing through the first washer, the through hole, the second washer and the connecting hole in order, the first fastener fixed on the panel by the second fastener, and the handle board rotatable only about the through hole as a center,
wherein the server case comprises a frame plate disposed on a side thereof adjacent to the panel, the fixing section comprises a first engaging block and a second engaging block, and when the panel abuts against the frame plate and the handle board is unrotated, the first engaging block and the second engaging block are correspondingly located on two sides of the frame plate, and when the panel abuts against the frame plate and the handle board is fully rotated, the first engaging block and the second engaging block are located on same side of the frame plate,
wherein the frame plate comprises a slit, the fixing section comprises a third engaging block disposed spacedly on a side of the first engaging block to have the frame plate located between the first engaging block and the third engaging block, and the third engaging block abuts against the frame plate when the handle board is unrotated, and the first engaging block abuts against the frame plate after the handle board is rotated.

2. (canceled)

3. (canceled)

4. The handle structure of claim 1, wherein a U-shaped opening is disposed between the first engaging block and the third engaging block, and the U-shaped opening is located on a side of the slit.

5. The handle structure of claim 1, wherein the first fastener comprises a screw and the second fastener comprises a nut.

6. The handle structure of claim 5, wherein the second fastener is positioned on the connecting hole of the panel.

7. The handle structure of claim 1, wherein the panel comprises a protrusive plate and a hollow trench located on a side of the protrusive plate, the protrusive plate comprises the connecting hole, and the fixing section is located in the hollow trench.

8. The handle structure of claim 1, wherein the holding section comprises an arcuate surface located on a distal end of the holding section and facing the panel.

9. The handle structure of claim 1, wherein each washer comprises a plastic spacer.

10. The handle structure of claim 1, wherein the handle board comprises a chamfer disposed on a periphery thereof.
